(19) United States
(12) Patent Application Publication
(10) Pub. No.: US 2026/0089994 A1
(43) Pub. Date: Mar. 26, 2026

(54) SEMICONDUCTOR DEVICE AND MANUFACTURING METHOD THEREOF

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Min-Hung LEE, New Taipei City (TW); Cheng-Hong LIU, Changhua County (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/895,825

(22) Filed: Sep. 25, 2024

(51) Int. Cl. H01L 29/66; H01L 29/06; H01L 29/423; H01L 29/775; H01L 29/786

(52) U.S. Cl. CPC H10D 30/014; H10D 30/43; H10D 30/6735; H10D 30/6757; H10D 62/122

(57) ABSTRACT

A method for manufacturing a semiconductor device is provided. The method includes patterning a semiconductor layer into a channel layer, wherein the semiconductor layer is over a dielectric layer on a substrate; removing a first portion of the dielectric layer below the channel layer to turn channel layer, such that have a first end of the channel layer is higher than a second end of the channel layer; and forming a gate structure over the channel layer.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a semiconductor device in accordance with some embodiments of the present disclosure.

FIGS. 2A-9 illustrate schematic views of intermediate stages in the manufacture of a semiconductor device in accordance with some embodiments of the present disclosure.

FIGS. 10-12 illustrate schematic views of intermediate stages in the manufacture of a semiconductor device in accordance with some embodiments of the present disclosure.

FIGS. 13-22C illustrate schematic views of intermediate stages in the manufacture of a semiconductor device in accordance with some embodiments of the present disclosure.

FIGS. 23 and 24 illustrate schematic views of intermediate stages in the manufacture of a semiconductor device in accordance with some embodiments of the present disclosure.

FIG. 25 is a diagram illustrating an enhancement factor of drive current versus a width of footprint of channel layers in semiconductor devices in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “multi-gate device” is used to describe a device (e.g., a semiconductor transistor) that has at least some gate material disposed on multiple sides of at least one channel of the device. In some examples, the multi-gate device may be referred to as a gate all around (GAA) device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

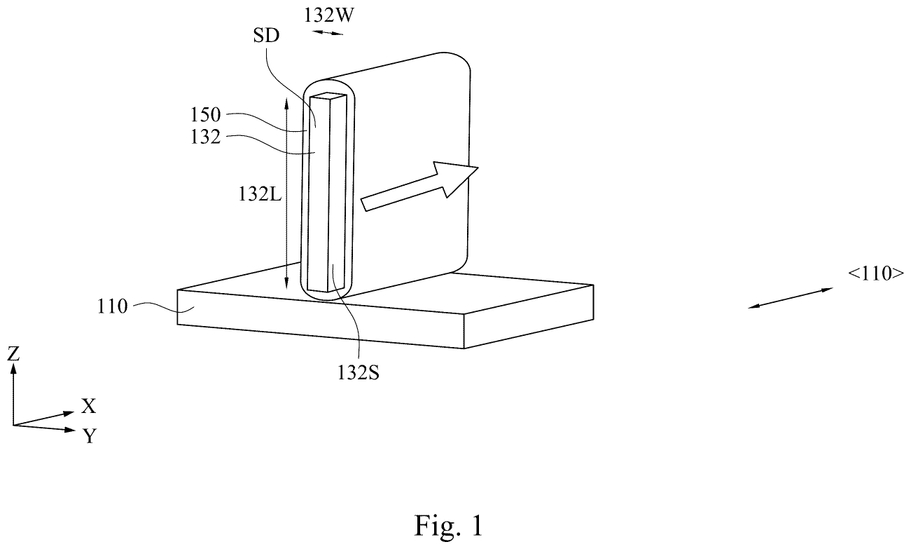

FIG. 1 is a schematic view of a semiconductor device in accordance with some embodiments of the present disclosure. The semiconductor device includes a channel layer 132 over a substrate 110 and a gate structure 150 surrounding a channel region of the nanofin 132. Source/drain regions SD may be doped regions formed in the channel layer 132 or epitaxial features formed on opposite sides of the channel region of the nanofin 132. In some embodiments, current flows (e.g., electrons are transported) from one of the source/drain regions SD to another one of the source/drain regions SD along <110> direction of the channel layer 132 along a current direction, which is referred to as a direction X in the context. The surface 132S of the channel layer 132 has (100) surface orientation, which exhibits higher electron mobility in a n-type semiconductor device. The channel layer 132 may be a non-horizontal nanosheet. For example, the surface 132S of the channel layer 132 is non-parallel to a top surface of the substrate 110, thereby maintaining high electron mobility characteristic and achieving the footprint shrinking. In some embodiments, the channel layer 132 may act as a vertical nanosheet, also referred to as a nanofin. Over a plane perpendicular to the current direction X (e.g., over the Y-Z plane), the nanofin 132 may have a length 132L and a width 132W. In some embodiments, for the vertical nanofin, the length 132L can be measured along a direction Z normal to a top surface of the substrate 110, and the width 132W measured along a direction Y substantially perpendicular to the directions X and Z. For achieving the nanofin configuration, the length 132L is greater than the width 132W. For example, a ratio of the length 132L and the width 132W may be in a range from about 1.2 to about 4000.

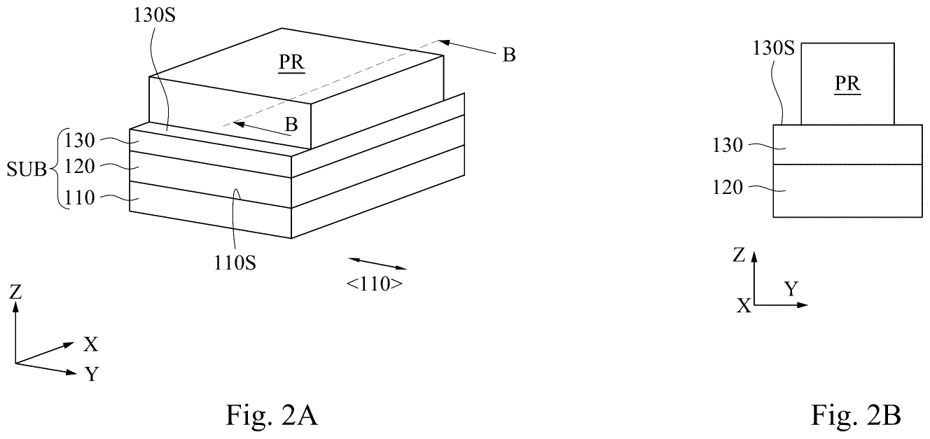

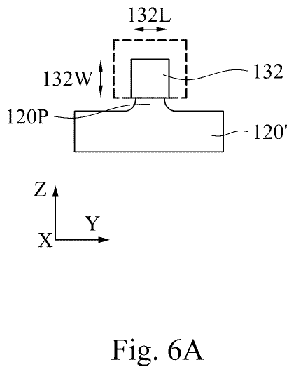

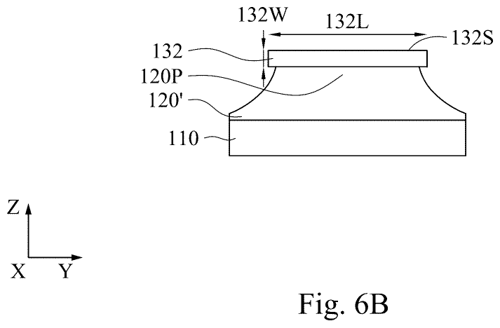

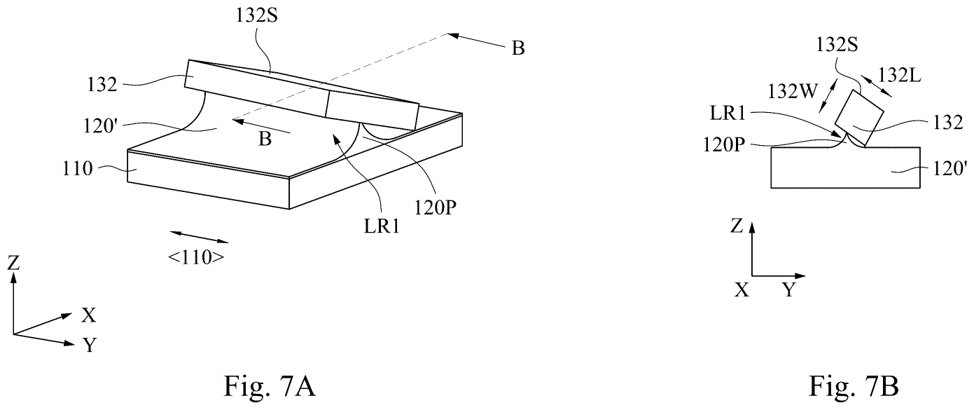

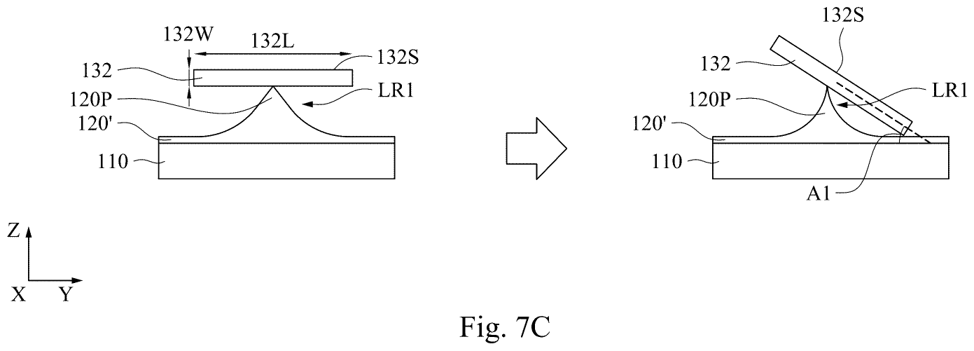

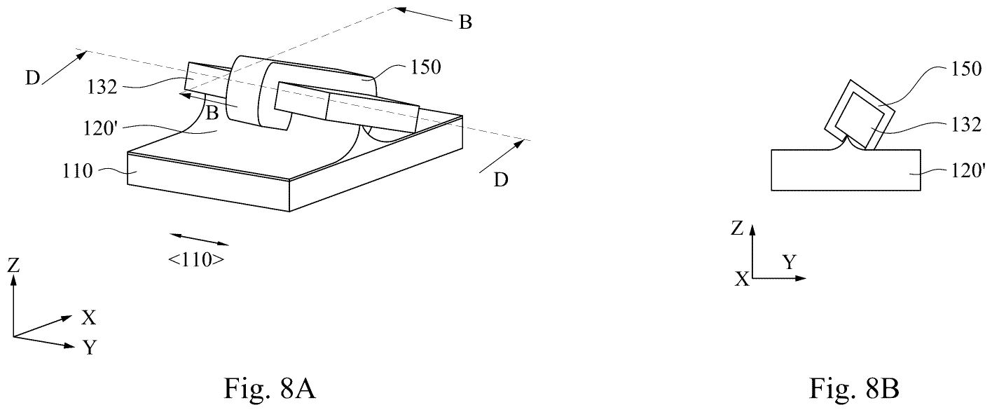

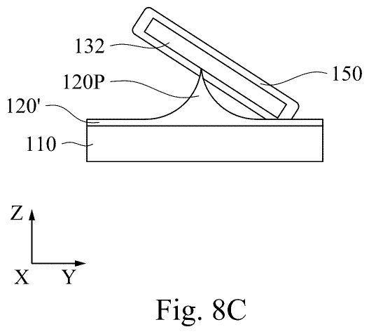

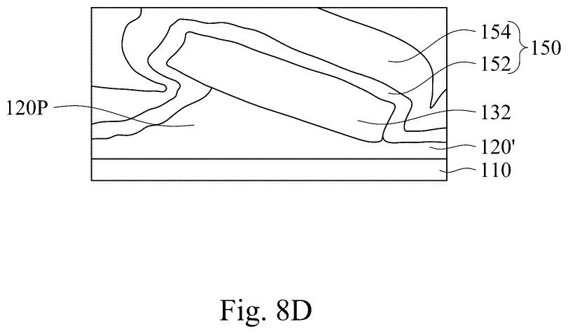

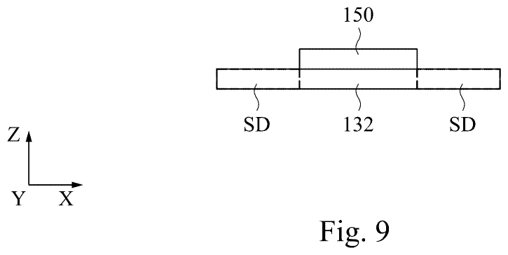

FIGS. 2A-9 illustrate schematic views of intermediate stages in the manufacture of a semiconductor device in accordance with some embodiments of the present disclosure. FIGS. 2A, 3A, 5A, 7A, and 8A are schematic views of the semiconductor device at various manufacturing stages in accordance with some embodiments. FIGS. 2B, 3B, 4, 5B, 6A, 7B, and 8B are cross-sectional views of the semiconductor device (e.g., taken along line B-B in FIGS. 2A, 3A, 5A, 7A, and 8A) at various manufacturing stages in accordance with some embodiments. FIG. 9 is a cross-sectional view of the semiconductor device (e.g., taken along line D-D in FIG. 8A) at a manufacturing stage in accordance with some embodiments. FIG. 6B is a cross-sectional view illustrating an example of the semiconductor device of FIG. 6A. FIG. 7C shows a process for forming the semiconductor device of FIGS. 7A and 7B in accordance with some embodiments. FIG. 8C is a cross-sectional view illustrating an example of the semiconductor device of FIG. 8B. It is understood that additional steps may be provided before, during, and after the steps shown in FIGS. 2A-9, and some of the steps described below can be replaced or eliminated for additional embodiments of the method. The order of the operations/processes may be interchangeable.

Reference is made to FIGS. 2A and 2B. The substrate SUB may be a semiconductor-on-insulator (SOI) including a substrate 110, a buried dielectric layer 120, and a semiconductor layer 130. In some embodiments, the substrate 110 may include silicon (Si), germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the semiconductor layer 130 may include silicon (Si), germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. The substrate 110 may have a top surface 110S with (100) surface orientation, which exhibits higher electron mobility in a n-type semiconductor device. And, by epitaxial growth from the substrate 110, the semiconductor layer 130 may also have a top surface 130S with (100) surface orientation. The buried dielectric layer 120 may be a buried oxide (BOX) layer, such as that formed by a method referred to as separation by implantation of oxygen (SIMOX) technology, wafer bonding, selective epitaxial growth (SEG), or another appropriate method. In some alternative embodiments, the substrate SUB may include a substrate 110, a dielectric layer 120 deposited over the substrate 110 by suitable deposition process, and a semiconductor layer 130 over the dielectric layer 120. The dielectric layer 120 may include any suitable dielectric materials, such as silicon oxide, silicon nitride, the like, or the combination thereof. The semiconductor layer 130 may include semiconductor materials, oxide semiconductor materials, two-dimensional semiconductor material (e.g., ( transition-metal dichalcogenides (TMD)), the like, or the combination thereof. A thickness of the buried dielectric layer 120 can be selected/controlled for achieving desired rotation angle of a channel layer in subsequent process.

In some embodiments, the semiconductor layer 130 is an intrinsic semiconductor layer, which is not intentionally doped, for example, not having intentionally placed dopants, but rather having a doping resulting from process contaminants. In some embodiments, the semiconductor layer 130 is substantially dopant-free (i.e., having an extrinsic dopant concentration from about 0 cm⁻³ to about 1×10¹³ cm⁻³), where for example, no intentional doping is performed during the epitaxial growth process. In some embodiments, the semiconductor layer 130 can be lightly doped with p-type dopants or n-type dopants (i.e., having an extrinsic dopant concentration from about 1×10¹³ cm⁻³ to about 1×10¹⁸ cm⁻³).

A photomask PR may be formed over the substrate SUB by a photolithography process. The photolithography process may include forming a photoresist layer (not shown), exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process. In some embodiments, the photomask PR extend along <110> direction of the semiconductor layer 130 (e.g., the direction X), thereby providing a pattern for channels subsequently formed.

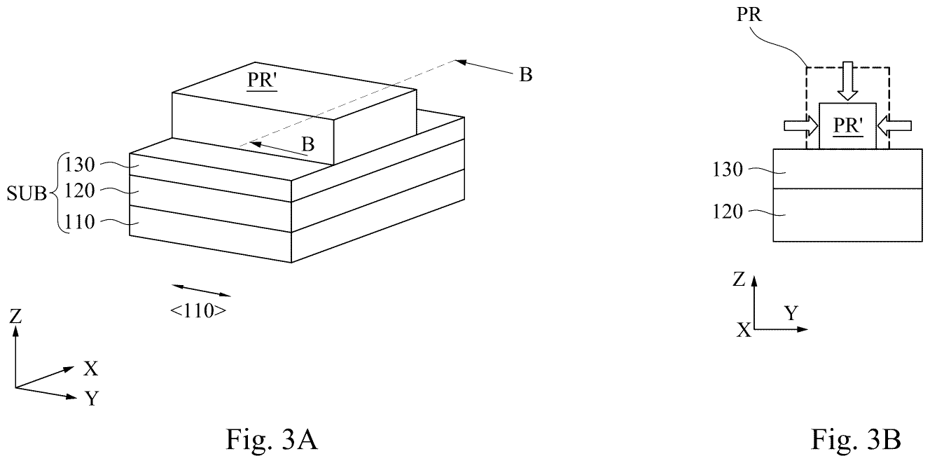

Reference is made to FIGS. 3A and 3B. A photoresist trimming process is performed so that a width/height of the photoresist pattern after the photoresist trimming process is less than a width/height of the photoresist pattern before the photoresist trimming process (as indicated by the dashed line). After the photoresist trimming process, the trimmed photomask may be referred to as a photomask PR′ hereinafter.

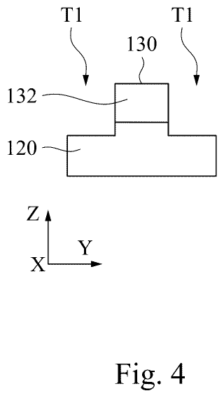

Reference is made to FIG. 4. The photomask PR′ (referring to FIGS. 3A and 3B) may protect regions of the substrate 110, and layers formed thereupon, while an etch process forms trenches T1 in unprotected regions through the semiconductor layer 130, thereby leaving at least one channel layer 132. The trenches T1 may expose the dielectric layer 120. The trenches T1 may be etched using a dry etch (e.g., reactive ion etching), a wet etch, and/or combination thereof. The top surface 132S of the channel layer 132 may have (100) surface orientation, which exhibits higher electron mobility in a n-type semiconductor device. Numerous other embodiments of methods to form the channel layer 132 on the substrate 110 may also be used including, for example, defining the region (e.g., by mask or isolation regions) and epitaxially growing semiconductor materials in the form of the channel layer 132. After the etching process, the photomask PR′ (referring to FIGS. 3A and 3B) may be removed by a suitable stripping process.

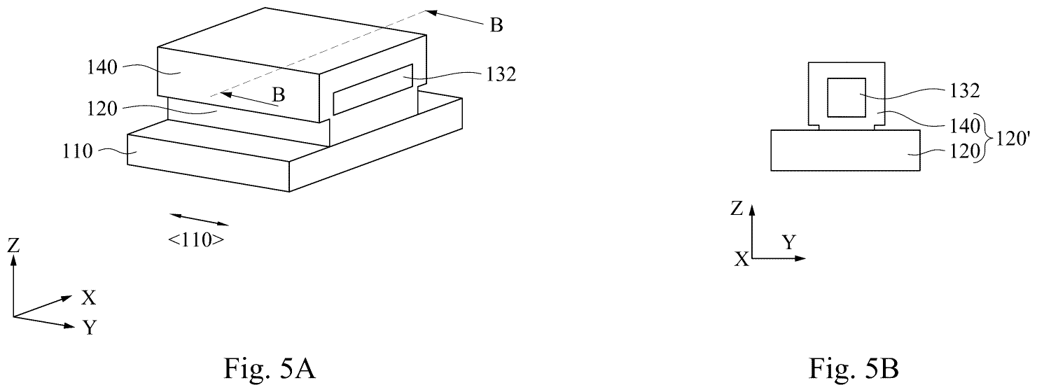

Reference is made to FIGS. 5A and 5B. An oxidation process is performed to oxide a surface portion of the channel layer 132, thereby turning the surface portion of the channel layer 132 into a semiconductor oxide layer 140. The semiconductor oxide layer 140 may include a same semiconductor element as that of the channel layer 132. For example, in some embodiments where the channel layer 132 include silicon, the semiconductor oxide layer 140 may include silicon oxide. In some embodiments, the semiconductor oxide layer 140 and the dielectric layer 120 may comprise a same material. The semiconductor oxide layer 140 and the dielectric layer 120 in combination may be referred to as a dielectric layer 120′. After the oxidation process, the channel layer 132 is trimmed to have a small size. For example, over a plane perpendicular to the current direction X (e.g., over the Y-Z plane), a length 132H of the channel layer 132 is greater than a width 132W of the channel layer 132. For example, a ratio of the length 132L and the width 132W may be in a range from about 1.5 to about 4000. In some alternative embodiments, the oxidation process may be omitted, and the channel layer 132 can be formed with the desired ratio by the previous steps.

Reference is made to FIGS. 6A and 6B. An etch process is performed to remove portions of the dielectric layer 120′ on a top surface and sidewalls of the channel layer 132, thereby leaving the channel layer 132 exposed by the dielectric layer 120'. The etch process may include a dry etch, a wet etch, or the combination thereof. The etch process may vertically etch the dielectric layer 120′, such that the channel layer 132 may stand over a protruding portion 120P of the dielectric layer 120′.

Reference is made to FIGS. 7A-7C. A wet etching process is performed to laterally etch the protruding portion 120P of the dielectric layer 120′, thereby forming a lateral recess LR1 below the channel layer 132 around the protruding portion 120P of the dielectric layer 120′. When the lateral recess LR1 becomes large, the protruding portion 120P of the dielectric layer 120′ may become too thinned to support the channel layer 132, such that the channel layer 132 may turn. For example, the channel layer 132 falls down from the protruding portion 120P of the dielectric layer 120′ with a certain degree of rotation. For example, the channel layer 132 may rotate with respect to a top end of the protruding portion 120P of the dielectric layer 120'. The protruding portion 120P of the dielectric layer 120′ may be removed by further continuing the etch processes (e.g., the wet etch) or other suitable etch/removal process. As a result, as shown in the drawings, a first end of the channel layer 132 is higher than a second end of the channel layer 132. The first end of the channel layer 132 is higher than a top end of the protruding portion 120P of the dielectric layer 120', and the second end of the channel layer 132 is lower than a top end of the protruding portion 120P of the dielectric layer 120′.

In the present embodiments, the channel layer 132 is rotated by an angle A1 in a range from about 10 degrees to about 90 degrees. In the illustrated embodiments, by controlling etching parameters of the wet etching process (e.g., etching recipe, etching duration, or the like) and adjusting/controlling a thickness of the dielectric layer 120, the angle A1 is less than about 45 degrees, for example, in a range from about 10 degrees to about 45 degrees, or from about 20 degrees to about 45 degrees. In some embodiments, the channel layer 132 may act as a tilted nanosheet, and the top surface 132S of the channel layer 132 with (100) surface orientation is tilted. In the context, the angle A1 may be the angle A1 between a top surface of the substrate 110 and the surface 132S of the channel layer 132 (e.g., (100) surface orientation of the channel layer 132).

Reference is made to FIGS. 8A-8C. FIG. 8D is an exemplary cross-sectional view of a semiconductor device in accordance with some embodiments of the present disclosure. A gate structure 150 is formed around the channel layer 132. The gate structure 150 may include a gate dielectric layer 152 formed around the channel layer 132 and a gate electrode layer 154 formed around the gate dielectric layer. The gate dielectric layer 152 may include oxides, high-k gate dielectrics, ferroelectric materials, anti-ferroelectric materials, the like, or the combination thereof. The gate dielectric layer 152 may be deposited by an ALD process and/or a CVD process. For example, the gate dielectric layer 152 may include HfO₂, ZrO₂, HfZrO₂ (HZO), Al-doped HfO₂ (HAO), Si-Doped HfO₂ (HSO), PZT, SBT, AlScN. In some embodiments where the gate dielectric layer 152 include a mixture of anti-ferroelectric material and dielectric materials, the gate dielectric layer 152 may include SiO₂, Al₂O₃, HfO₂, ZrO₂, TiO₂. The gate electrode layer 154 may include a work functional metal layer formed around the gate dielectric layer 152 and a fill metal (optionally, not shown) filling a remaining space around the a work functional metal layer. The gate electrode layer 154 may include tungsten, aluminum, copper, nickel, cobalt, platinum, molybdenum, titanium, tantalum, titanium nitride, tantalum nitride, nickel silicide, cobalt silicide, other silicides, TaC, TaSiN, TaCN, TiAl, TiAlN, or other suitable materials. The gate electrode layer 154 may be deposited by an ALD process and/or a PVD process.

Reference is made to FIG. 9. After the formation of the metal gate structure 150, source/drain regions SD are formed in the channel layer 132 through one or more suitable implantation processes. In some embodiments, a photomask mask is formed by a photolithography process first, and the implantation process is performed using the photomask mask as an implantation mask defining positions of the source/drain regions SD. In some alternative embodiments, the implantation process is performed using the metal gate structure 150 as an implantation mask. Source/drain metal contact may then formed on the source/drain regions SD for electrical connection. The gate electrode layer 154 may include tungsten, aluminum, copper, nickel, cobalt, platinum, molybdenum, titanium, tantalum, titanium nitride, tantalum nitride, nickel silicide, cobalt silicide, other silicides, TaC, TaSiN, TaCN, TiAl, TiAlN, or other suitable materials. A back-side power delivery network (BSPDN) compatibility can be formed after the formation of the device.

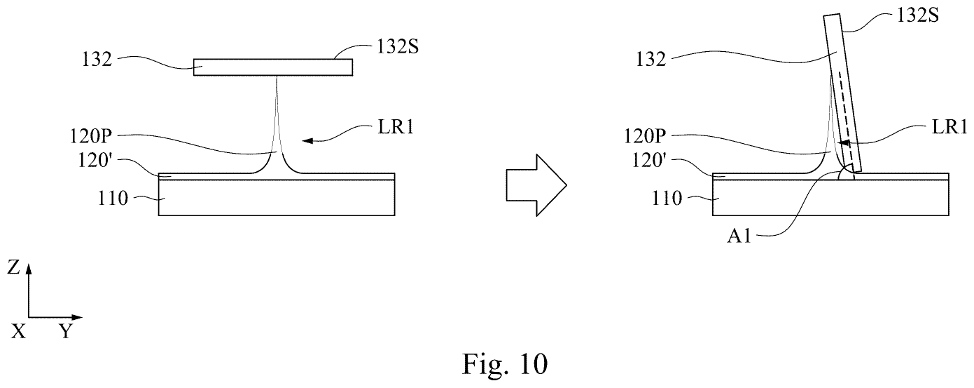

FIGS. 10-12 illustrate schematic views of intermediate stages in the manufacture of a semiconductor device in accordance with some embodiments of the present disclosure. Details of the present embodiments are similar to those illustrated in the embodiments in FIGS. 2A-9, except that the channel layer 132 is rotated by an angle A1 greater than about 45 degrees. It is understood that additional steps may be provided before, during, and after the steps shown in FIGS. 10-12, and some of the steps described below can be replaced or eliminated for additional embodiments of the method. The order of the operations/processes may be interchangeable.

Reference is made to FIG. 10. After the dielectric layer 120′ is etched to expose the channel layer 132 (referring to FIGS. 6A and 6B), the lateral recess LR1 is formed below the channel layer 132 around the protruding portion 120P of the dielectric layer 120′ by a wet etching process. As aforementioned, when the lateral recess LR1 becomes large, the protruding portion 120P of the dielectric layer 120′ may become too thinned to support the channel layer 132, such that the channel layer 132 may fall down from the protruding portion 120P of the dielectric layer 120′ with a certain degree of rotation. For example, the lateral stacks S1 may rotate with respect to top ends of the protruding portions 210P of the dielectric layer 210. The protruding portions 210P of the dielectric layer 210 may be removed by further continuing the etch processes (e.g., the wet etch) or other suitable etch/removal process.

In the illustrated embodiments, by controlling etching parameters of the wet etching process (e.g., etching recipe, etching duration, or the like), the channel layer 132 can be rotated by an angle A1 greater than about 45 degrees. For example, the angle A1 is in a range from about 45 degrees to about 90 degrees. In the illustrated embodiments, the angle A1 may be about 90 degrees. Through the configuration, the channel layer 132 stands almost vertically over the substrate. The surface 132S of the channel layer 132 with (100) surface orientation may be almost vertical to a top surface of the substrate 110. In some embodiments, the channel layer 132 may act as a vertical nanosheet, also referred to as a nanofin.

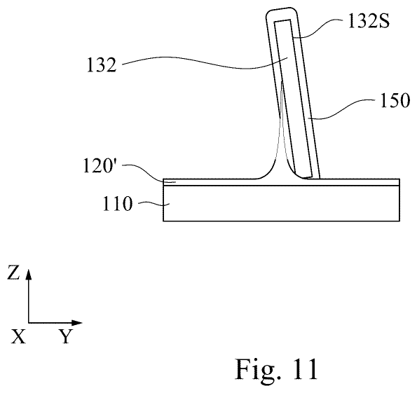

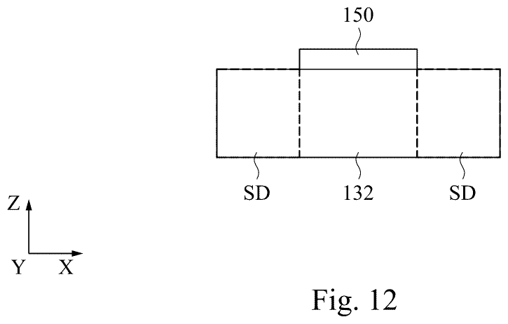

Reference is made to FIG. 11. A metal gate structure 150 is formed around the channel layer 132. Reference is made to FIG. 12. After the formation of the metal gate structure 150, source/drain regions SD are formed in the channel layer 132 through one or more suitable implantation processes. A back-side power delivery network (BSPDN) compatibility can be formed after the formation of the device. Other details of the present embodiments are similar to those illustrated in the embodiments in FIGS. 2A-9, and thereto not repeated herein.

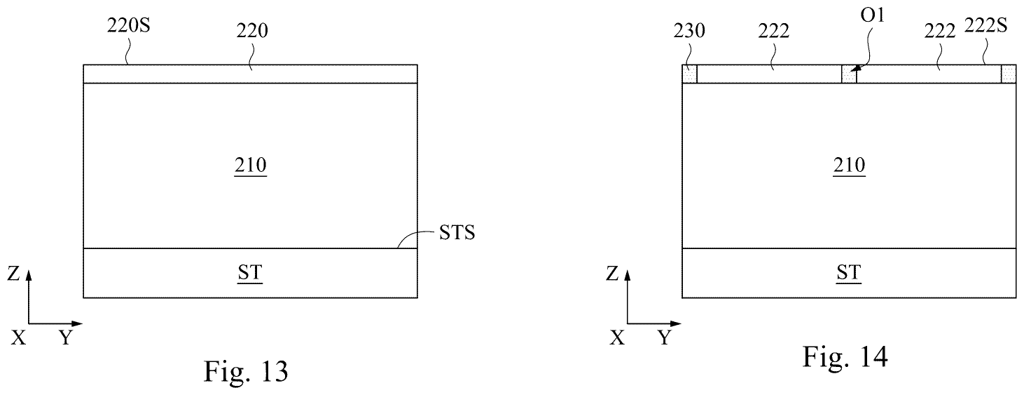

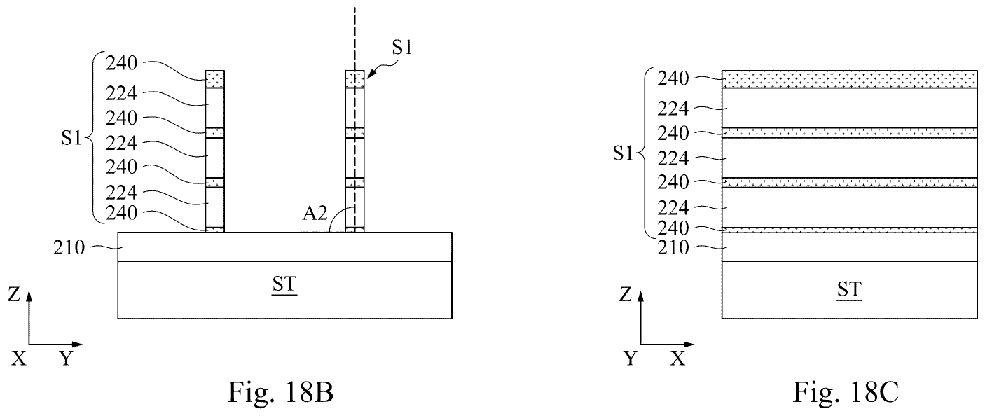

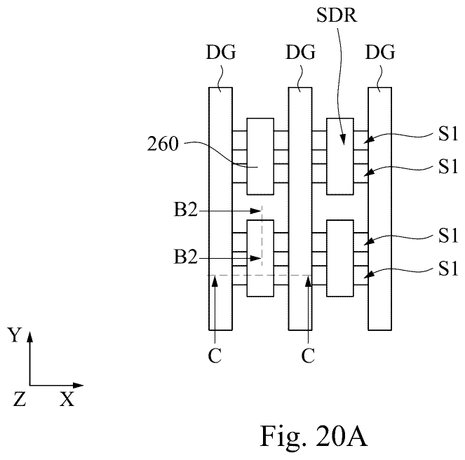

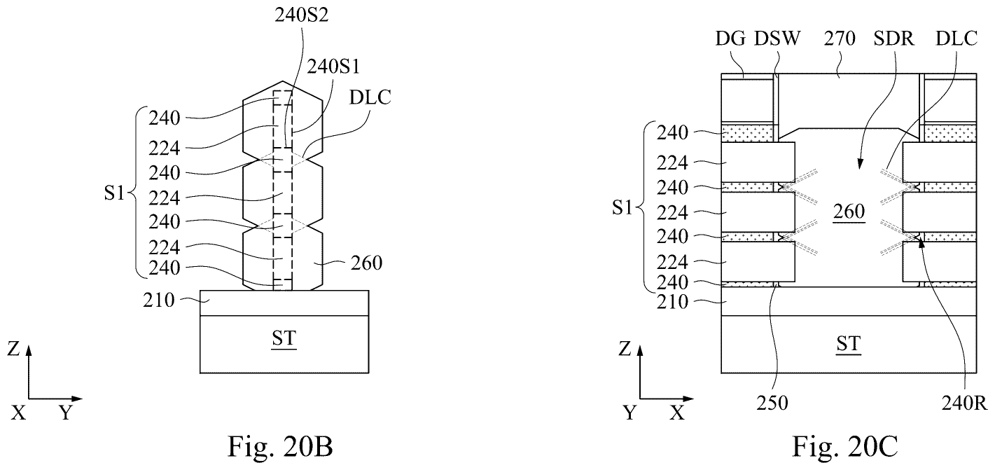

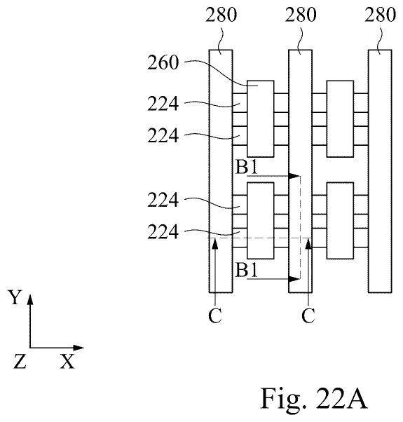

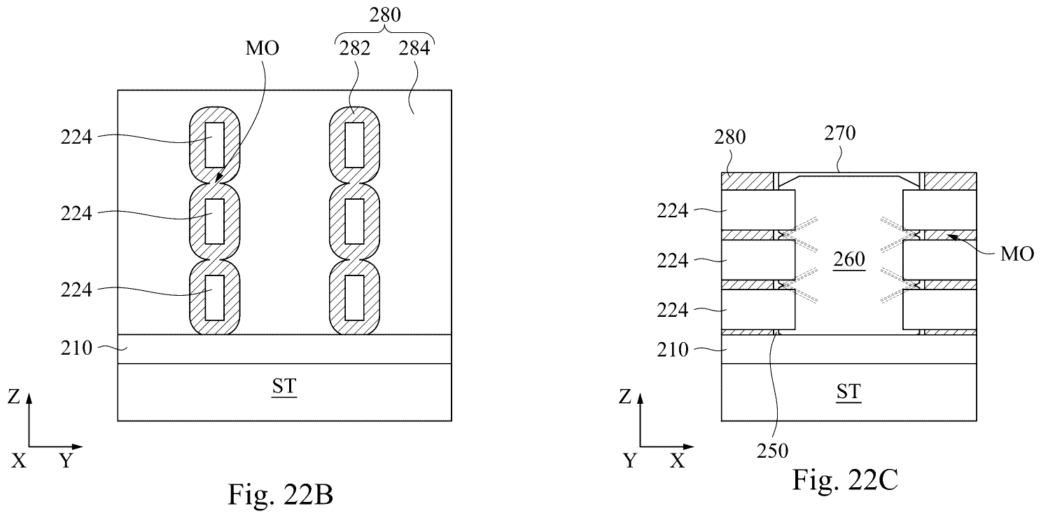

FIGS. 13-22C illustrate schematic views of intermediate stages in the manufacture of a semiconductor device in accordance with some embodiments of the present disclosure. FIGS. 18A, 19A, 20A, and 22A are top views of the semiconductor device at various manufacturing stages in accordance with some embodiments. FIGS. 13-17, 18B, 21A, and 22B are cross-sectional views of the semiconductor device (e.g., taken along line B1-B1 in FIGS. 18A and 22A) at various manufacturing stages in accordance with some embodiments. FIG. 20B is a cross-sectional view of the semiconductor device (e.g., taken along line B2-B2 in FIG. 20A) at various manufacturing stages in accordance with some embodiments. FIGS. 18C, 19B, 20C, 21B, and 22C are cross-sectional views of the semiconductor device (e.g., taken along line C-C in FIGS. 18A, 20A, and 22A) at various manufacturing stages in accordance with some embodiments. Details of the present embodiments are similar to those illustrated in the embodiments in FIGS. 2A-9 and FIGS. 10-12, except that plural vertical channel layers are vertically aligned with each other by rotating a stack of the plural vertical channel layers. It is understood that additional steps may be provided before, during, and after the steps shown in FIGS. 13-22C, and some of the steps described below can be replaced or eliminated for additional embodiments of the method. The order of the operations/processes may be interchangeable.

Reference is made to FIG. 13. A dielectric layer 210 is formed over a semiconductor substrate SUB, and a semiconductor layer 220 is formed over a dielectric layer 210. The dielectric layer 210 may include a suitable dielectric material, such as silicon oxide, silicon nitride, the like, or the combination thereof. In some embodiments, the semiconductor layer 220 may include suitable semiconductor materials, such as silicon (Si), germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some other embodiments, the semiconductor layer 220 may include oxide semiconductor materials or two-dimensional semiconductor material. The semiconductor substrate ST may have a top surface STS with (100) surface orientation, and the semiconductor layer 220 may have a top surface 220S with (100) surface orientation, which exhibits higher electron mobility in a n-type semiconductor device. In some embodiments, the semiconductor substrate SUB, the dielectric layer 210 and the semiconductor layer 220 may be layers of an SOI substrate. In some embodiments, the semiconductor substrate ST may be omitted, and the layer 210 can serve as the substrate.

Reference is made to FIG. 14. The semiconductor layer 220 is patterned into a plurality of semiconductor layers 222. The semiconductor layers 222 may have top surfaces 222S with (100) surface orientation. The patterning process may include a lithography process and an etching process following the lithography process. The photolithography process may include forming a photoresist layer (not shown), exposing the photoresist to a pattern, performing post-exposure bake processes, and developing the resist to form a patterned mask including the resist. The etching process may remove portions of the semiconductor layer 220 exposed by the patterned mask, while portions of the semiconductor layer 220 covered by the patterned mask are prevented from being etched. The etching process may result in openings O1 exposing the dielectric layer 210, in which the semiconductor layers 222 are spaced apart from each other by the openings O1.

After the formation of the openings O1, isolation features 230 are formed in the openings O1. Formation of the isolation features 230 may include depositing a suitable dielectric material (e.g., silicon oxide) into the openings O1, followed by a planarization process (e.g., chemical mechanical polish (CMP) process). The planarization process may remove excess portions of the dielectric material external to the openings O1. After the planarization process, remaining portions of the dielectric material in the openings O1 form the isolation features 230.

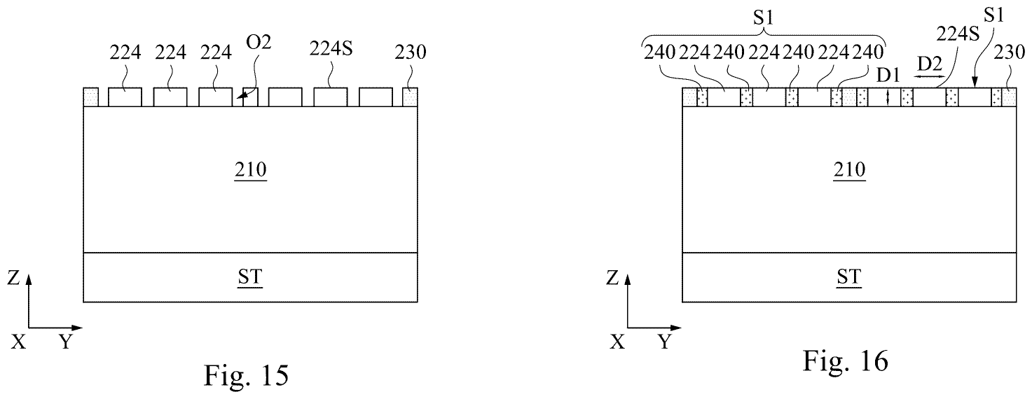

Reference is made to FIG. 15. Each of the semiconductor layers 222 is patterned into a plurality of channel layers 224. The channel layers 224 may have a top surface 224S of (100) surface orientation, which exhibits higher electron mobility in a n-type semiconductor device. The channel layers 224 may be level and aligned with each other along the direction Y. In some embodiments, for achieving as nanofins, a length of the channel layers 224 measured along the direction Y is greater than a height of the channel layers 224 measured along the direction Z. The patterning process may include a lithography process and an etching process following the lithography process. The photolithography process may include forming a photoresist layer (not shown), exposing the photoresist to a pattern, performing post-exposure bake processes, and developing the resist to form a patterned mask including the resist. The etching process may remove portions of the semiconductor layers 222 exposed by the patterned mask, while portions of the semiconductor layers 222 covered by the patterned mask are prevented from being etched. The etching process may result in openings O2 exposing the dielectric layer 210, in which the channel layers 224 are spaced apart from each other by the openings O2.

Reference is made to FIG. 16. Sacrificial layers 240 are formed the openings O2. The sacrificial layers 240 may have a different semiconductor composition from the channel layers 224. In some embodiments, the channel layers 224 and the sacrificial layers 240 may include SiGe with various semiconductor compositions. For example, a Si concentration in the sacrificial layers 240 is less than a Si concentration in the channel layers 224. Stated differently, in the embodiments, a Ge concentration in the sacrificial layers 240 is greater than a Ge concentration in the channel layers 224. For example, the channel layers 224 are SiₓGe₁₋ₓ, and the sacrificial layers 240 are Si_{y}Ge_{1-y}, in which x and y are in a range from 0 to 1, and x>y. However, other embodiments are possible including those that provide for the material/compositions having different oxidation rates and/or etch selectivity. In some embodiments where the sacrificial layers 240 include SiGe and the channel layers 224 include Si, the Si oxidation rate of the channel layers 224 is less than the SiGe oxidation rate of the sacrificial layers 240. In some embodiments, a length of the channel layers 224 measured along the direction Y is greater than a length of the sacrificial layers 240 measured along the direction Y.

By way of example, epitaxial growth of the sacrificial layers 240 may be performed by a molecular beam epitaxy (MBE) process, a metalorganic chemical vapor deposition (MOCVD) process, and/or other suitable epitaxial growth processes. In some embodiments, the epitaxially grown layers such as, the sacrificial layers 240 include suitable semiconductor material, such as like Si, Ge, Sn, SiGe, GeSn, III-V semiconductor, the like, or the combination thereof. For example, the sacrificial layers 240 include suitable semiconductor material, such as Si, Ge, SiGe, GeSn, III-V semiconductor, the like, or the combination thereof. In some other embodiments, the sacrificial layers 240 may include other materials such as a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. As discussed, the materials of the the sacrificial layers 240 may be chosen based on providing differing oxidation and/or etching selectivity properties than the channel layers 224. In some embodiments, the sacrificial layers 240 are intrinsic semiconductor layers, which are not intentionally doped, for example, not having intentionally placed dopants, but rather having a doping resulting from process contaminants. In some embodiments, the sacrificial layers 240 are substantially dopant-free (i.e., having an extrinsic dopant concentration from about 0 cm⁻³ to about 1×10¹⁸ cm⁻³), where for example, no intentional doping is performed during the epitaxial growth process.

In some embodiment, after the epitaxial growth of the semiconductor materials of the sacrificial layers 240, a planarization process (e.g., CMP process) is optionally performed to remove excess portions of the semiconductor material external to the openings O2. After the planarization process, remaining portions of the semiconductor material in the openings O2 form the sacrificial layers 240. In the context, a combination of the sacrificial layers 240 and the channel layers 224 between two adjacent ones of the isolation features 230 may be referred to as a lateral stack S1. The channel layers 224 may have a thickness D1 and a length D2 greater than the thickness D1, in which the thickness D1 and the length D2 may be adjusted according to the device requirement for nanofins.

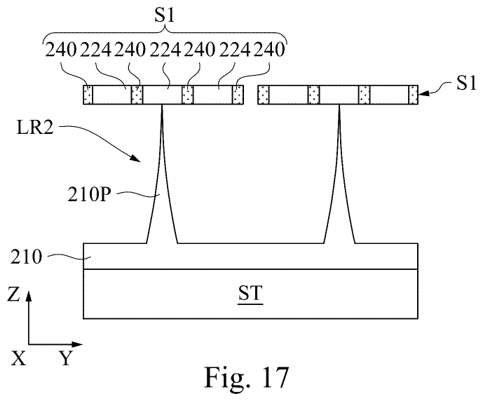

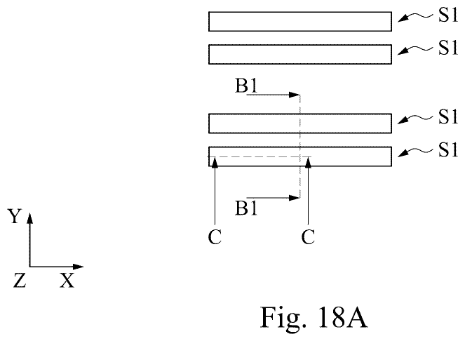

Reference is made to FIG. 17. One or more etch process are performed to remove the isolation features 230 and portions of the dielectric layer 210. The etch process may include a dry etch, a wet etch, or the combination thereof. The etch processes may result in a lateral recess LR2 below the lateral stack S1 and surrounding a protruding portion 210P of the dielectric layer 210. The lateral stacks S1 may be supported by the protruding portion 120P of the dielectric layer 210.

By continuing the etch processes (e.g., the wet etch), the lateral recess LR2 becomes large, and the protruding portions 210P of the dielectric layer 210 may become too thinned to support the lateral stacks S1, such that the lateral stacks S1 may fall down from the protruding portions 210P of the dielectric layer 210 with a certain degree of rotation. For example, the lateral stacks S1 may rotate with respect to top ends of the protruding portions 210P of the dielectric layer 210. The protruding portions 210P of the dielectric layer 210 may be removed by further continuing the etch processes (e.g., the wet etch) or other suitable etch/removal process. As a result, as shown in the FIGS. 18A-18C, a first end of the lateral stacks S1 is higher than a second end of the lateral stacks S1.

In the present embodiments, the lateral stacks S1 are rotated by an angle A2 in a range from about 10 degrees to about 90 degrees. In the illustrated embodiments, by controlling etching parameters of the wet etching process (e.g., etching recipe, etching duration, or the like), the angle A2 can be in a range from about 80 degrees to about 90 degrees (e.g., almost 90 degrees), thereby turning the stacks S1 from the lateral stacks into the vertical stacks. Through the configuration, the stacks S1 stand almost vertically over the substrate. The surface 224S of the channel layers 224 with (100) surface orientation may be almost vertical to a top surface of the substrate. For example, one of the channel layers 224 are directly above another one of the channel layers 224.

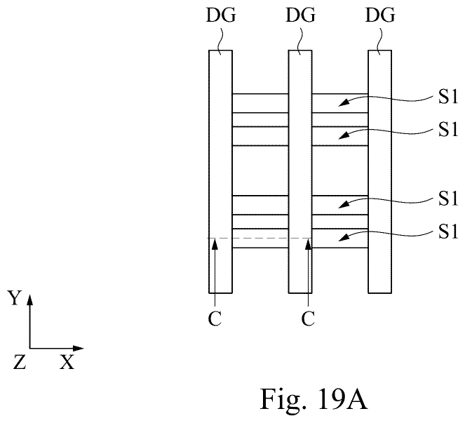

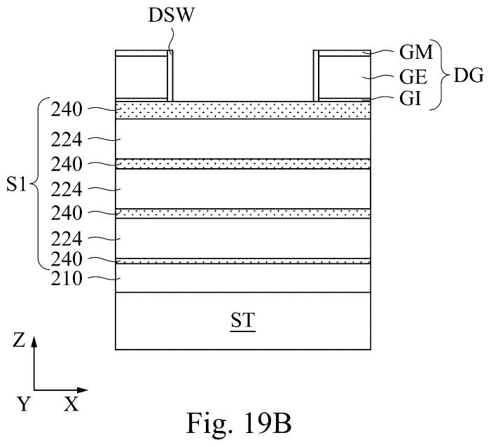

Reference is made to FIGS. 19A and 19B. One or more dummy gate structures DG are formed on the stacks S1. The dummy gate structure DG may include a gate dielectric GI, a gate electrode GE, and a hard mask GM. The gate dielectric GI may include one or more layers of dielectric material, such as silicon oxide, silicon nitride, a high-k dielectric material, and/or other suitable dielectric material. In some embodiments, the gate electrode GE includes a material different than that of the gate dielectric GI. In some embodiments, the gate dielectric GI may be deposited by a CVD process, a sub-atmospheric CVD (SACVD) process, a FCVD process, an ALD process, a PVD process, or other suitable process. The gate electrode GE may include polycrystalline silicon (polysilicon). The hard mask GM may include a silicon oxide layer and a silicon nitride layer. In some embodiments, the materials of the dummy gate structures DG are formed by various processes such as layer deposition, for example, CVD, PVD, ALD, thermal oxidation, or other suitable deposition techniques, or combinations thereof.

The dummy gate structures DG may be formed by first depositing a blanket gate dielectric layer, a gate electrode layer, and a mask layer, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the dielectric layer, the gate electrode layer, and the mask layer, the fins FS are partially exposed on opposite sides of the dummy gate structure DG.

Gate spacers GSW are formed on opposite sidewalls of the dummy gate structures DG. The gate spacer GSW may be made of a dielectric material such as silicon oxide, silicon nitride, silicon carbide, silicon oxynitride, SiCN, silicon oxycarbide, SiOCN, and/or combinations thereof. The gate spacers GSW may be formed by first depositing one or more conformal spacer material layers and subsequently etching back the one or more spacer material layers to form gate spacers GSW. The one or more conformal spacer material layers may be formed by ALD or CVD processes. The etching back process may include an anisotropic dry etch process. During the anisotropic dry etch process, most of the one or more spacer material layers are removed from horizontal surfaces, leaving the gate spacers GSW on the vertical surfaces, such as the sidewalls of the dummy gate structures DG.

Reference is made to FIGS. 20A-20C. Source/drain recesses SDR are etched in the lateral stacks S1 by using, for example, an anisotropic etching process that uses the dummy gate structures DG and the gate spacers GSW as an etch mask. The source/drain recesses SDR may extend through the channel layers 224 and the sacrificial layers 240 of the stacks S1. After the anisotropic etching, end surfaces of the channel layers 224 and the sacrificial layers 240 are exposed.

After the formation of the source/drain recesses SDR, the sacrificial layers 240 are laterally or horizontally recessed by using suitable selective etching process, resulting in lateral/sidewall recesses 240R vertically between corresponding channel layers 224. For example, end surfaces of the sacrificial layers 240 are recessed by the selective etching process. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. The channel layers 224 may have a higher etch resistance to the selective etching process than that of the sacrificial layers 240. In some embodiments, the selective etching includes SiGe oxidation followed by a SiGeOₓ removal. For example, the oxidation may be provided by an oxygen-containing cleaning process and then SiGeOₓ removed by the fluoride-based plasma (e.g., NF₃ plasma) that selectively etches SiGeOₓ at a faster etch rate than it etches Si. Moreover, because oxidation rate of Si is much lower (sometimes 30 times lower) than oxidation rate of SiGe (or Ge), the channel layers 224 may not be significantly etched by the process of laterally recessing the sacrificial layers 240. As a result, the channel layers 224 laterally extend past opposite end surfaces of the sacrificial layers 240.

Inner spacers 250 are formed in the lateral/sidewall recesses 240R. Stated differently, the inner spacers 250 may be formed on opposite end surfaces of the laterally recessed sacrificial layers 240. The inner spacers 250 may include a dielectric material, such as SiOₓ, SiON, SiOC, SiN, SiCN, or SiOCN. Formation of the inner spacers 250 may include depositing an inner spacer material layer, followed by an anisotropic etching process to trim the deposited inner spacer material layer. Through the anisotropic etching process, only portions of the deposited inner spacer material layer that fill the lateral/sidewall recesses 240R are left. The inner spacers 250 may include a single layer or multiple layers. The inner spacers 250 may serve to isolate metal gates from source/drain regions formed in subsequent processing.

Source/drain epitaxial structures 260 are formed in the source/drain recesses SDR on opposite sides of the channel layers 224 and on opposite sides of the dummy gate structure DG. The source/drain epitaxial structures 260 may be in contact with the exposed end surfaces of the channel layers 224. In some embodiments, the source/drain epitaxial structures 260 may include Ge, Si, GaAs, AlGaAs, SiGe, GaAsP, SiP, or other suitable material. The source/drain epitaxial structures 260 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 260 are not in-situ doped, an implantation process (i.e., a junction implant process) is performed to dope the source/drain epitaxial structures 260. The source/drain epitaxial structures 260 may be formed by performing an epitaxial growth process that provides an epitaxial material on the exposed surfaces of the channel layers 224. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the channel layers 224. After the formation of the source/drain epitaxial structures 260, a dielectric material 270 may be deposited over the source/drain epitaxial structures 260 and filling the space around the dummy gate structures DG, followed by a planarization process (e.g., CMP). In some embodiments, the dielectric material 270 includes a contact etch stop layer (CESL) and an interlayer dielectric (ILD) layer formed in sequence.

In some cases, in channel stacking, dislocations (e.g., dislocations lines DLC) may occur between the source/drain epitaxial structures on opposite sides of the channel layers. The dislocations may extensively occupy a large interface area in the cross-sectional areas of the source/drain epitaxial structures taken along the direction Y. The extensive dislocation interface area could induce additional stress to affect the quality of the source/drain epitaxial structures.

In some embodiments of the present embodiments, by designing the channel layers to be nanofins 224, which have narrow sides 224S2 facing each other, the source/drain epitaxial structures 260 may majorly grow from long sides 224S1 of the nanofins 224. The long sides 224S1 of the nanofins 224 may correspond to the top surface 220S of the semiconductor layer 220 (referring to FIG. 13), and therefore the long sides 224S1 of the nanofins 224 may have (100) surface orientation, which exhibits higher electron mobility in a n-type semiconductor device. As a result, the dislocation interface area between two adjacent the source/drain epitaxial structures 260 can be minimized, thereby significantly reducing the stacking faults.

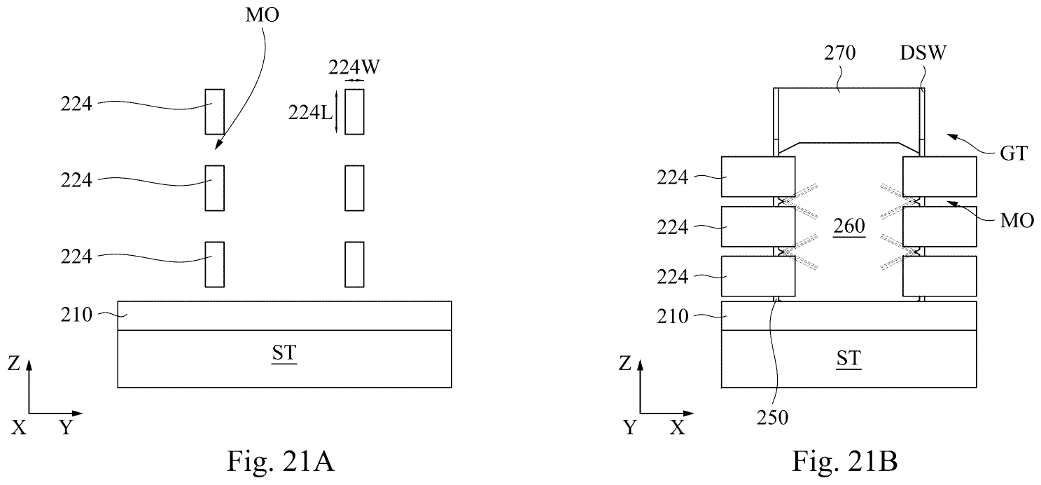

Reference is made to FIGS. 21A-22C. The dummy gate structure DG and the sacrificial layers 240 (referring to FIGS. 20B and 20C) are replaced with high-k/metal gate structures 280. In FIGS. 21A-21B, the dummy gate structure DG (referring to FIG. 20C) is removed, followed by removing the sacrificial layers 240 (referring to FIGS. 20B and 20C). In the illustrated embodiments, the dummy gate structure DG (referring to FIG. 20C) is removed by using a selective etching process (e.g., selective dry etching, selective wet etching, or a combination thereof) that etches the materials in dummy gate structures DG (referring to FIG. 20C) at a faster etch rate than it etches other materials (e.g., gate spacers GSW and/or the dielectric material 270), thus resulting in a gate trench GT between corresponding gate spacers GSW, with the sacrificial layers 240 (referring to FIGS. 20B and 20C) exposed in the gate trench GT. Subsequently, the sacrificial layers 240 (referring to FIGS. 20B and 20C) are removed by using a selective etching process that etches the sacrificial layers 240 (referring to FIGS. 20B and 20C) at a faster etch rate than it etches the channel layers 224, thus respectively forming openings/spaces MO between the channel layers 224 and between a bottommost one of the channel layers 224 and the substrate ST. The openings/spaces MO may expose the sidewalls of the inner spacers 250. In this way, the channel layers 224 become vertical nanosheets (or referred to as nanofins) suspended over the substrate ST and between the source/drain epitaxial structures 260. This step is also called a channel release process.

At this interim processing step, the openings/spaces MO surrounding the nanofins 224 may be filled with ambient environment conditions (e.g., air, nitrogen, etc). In some embodiments, the nanofins 224 can be interchangeably referred to as nanowires, nanoslabs and nanorings, depending on their geometry. For example, in some other embodiments, the channel layers 224 may be trimmed to have a substantial rounded shape (i.e., cylindrical) due to the selective etching process for completely removing the sacrificial layers 240 (referring to FIGS. 20B and 20C). In that case, the resultant channel layers 224 can be called nanowires.

In some embodiments of the present disclosure, the nanofins 224 has a high aspect ratio. For example, over a plane perpendicular to the current direction X (e.g., over the Y-Z plane), a length 224L of the nanofins 224 is greater than a width 224W of the nanofins 224. The width 224W of the nanofins 224 may be substantially equal to the thickness D1 of the channel layers 224 (referring to the FIG. 16) may be controlled by various steps in the formation process of the channel layers 224 (referring to the FIG. 16). The length 224L of the nanofins 224 may be controlled by the length D2 of the channel layers 224 (referring to the FIG. 16) may be controlled by various steps in the formation process of the channel layers 224 (referring to the FIG. 16). For example, a ratio of the length 224L of the nanofins 224 and the width 224W of the nanofins 224 may be in a range from about 1.5 to about 3600.

In some embodiments, the sacrificial layers 240 (referring to FIGS. 20B and 20C) are SiGe and the channel layers 224 are silicon allowing for the selective removal of the sacrificial layers 240 (referring to FIGS. 20B and 20C). In some embodiments, the selective dry etching may use chloride-based gases, such as CF₄, C₄F₈, the like, or the combination thereof. In some embodiments, the selective removal includes SiGe oxidation followed by a SiGeOₓ removal. For example, the oxidation may be provided by O₂ plasma and then SiGeOₓ is removed by the chloride-based plasma (e.g., CF₄/C₄F₈ plasma) that selectively etches SiGeOₓ at a faster etch rate than it etches Si, and stops on SiGe. The steps of SiGe oxidation and SiGeOₓ removal may be repeated until the sacrificial layers 240 (referring to FIGS. 19A and 19B) are removed. Moreover, because oxidation rate of Si is much lower (sometimes 30 times lower) than oxidation rate of SiGe, the channel layers 224 may remain substantially intact during the channel release process.

In FIGS. 22A-22C, replacement gate structures 280 are formed in the openings/spaces MO provided by the release of nanofins 224, thereby surrounding the nanofins 224 suspended over the substrate ST. The gate structures 280 may be final gates of GAA FETs. The final gate structures may be a high-k/metal gate stack. Like the gate structure 150 (referring to FIGS. 8A-8D), the gate structures 280 may include a gate dielectric layer formed around the nanofins 224 and a gate electrode layer formed around the gate dielectric layer. The gate electrode layer of the gate structures 280 may include a work functional metal layer formed around the gate dielectric layer and a fill metal (optionally) filling a remaining space around the work functional metal layer. Due to the high aspect ratio of the nanofins 224, the openings/spaces MO can be filled with the materials of the gate structures 280 easily, thereby the electrostatic control is improved to be more precise. A back-side power delivery network (BSPDN) compatibility can be formed after the formation of the nanofin device. Other details of the present embodiments are similar to those illustrated in the embodiments in FIGS. 2A-9 and FIGS. 10-12, and thereto not repeated herein.

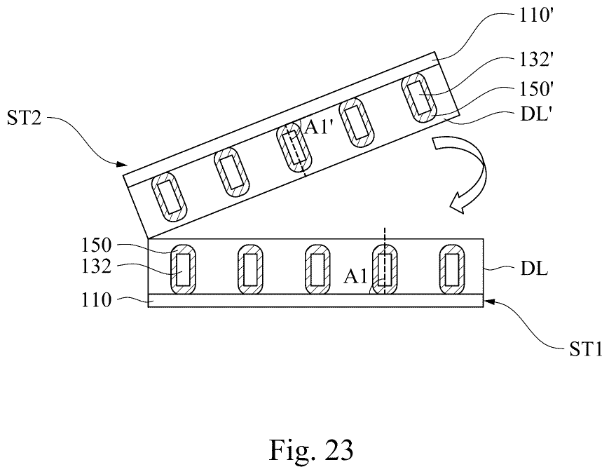

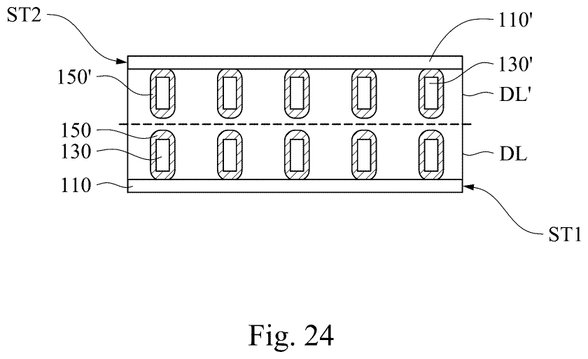

FIGS. 23 and 24 illustrate schematic views of intermediate stages in the manufacture of a semiconductor device in accordance with some embodiments of the present disclosure. Details of the present embodiments are similar to those illustrated in the embodiments in FIGS. 2A-9 and FIGS. 10-12, except that plural vertical channel layers are vertically aligned with each other by bonding two substrates with each other. It is understood that additional steps may be provided before, during, and after the steps shown in FIGS. 23 and 24, and some of the steps described below can be replaced or eliminated for additional embodiments of the method. The order of the operations/processes may be interchangeable.

Reference is made to FIG. 23. By the steps illustrated in FIGS. 2A-9 and FIGS. 10-12, a channel layer 132 can be formed over a substrate 110 with an angle A1 in a range from about 10 degree to about 90 degrees, and a gate structure 150 is formed around the channel layer 132. Subsequently, a bonding dielectric layer DL is formed over the gate structure 150, thereby resulting a semiconductor structure ST1 in FIG. 23. Similarly, by the steps illustrated in FIGS. 2A-9 and FIGS. 10-12, a channel layer 132′ can be formed over a substrate 110′ with an angle A1′ in a range from about 10 degree to about 90 degrees, and a gate structure 150′ is formed around the channel layer 132′. Subsequently, a bonding dielectric layer DL′ is formed over the gate structure 150′, thereby resulting a semiconductor structure ST2 in FIG. 23. In the illustrated embodiments, the angles A1 and A1′ may be about 90 degrees. Through the configuration, the channel layers 132/132′ stands almost vertically over the substrates 110/110′.

The semiconductor structure ST2 is flipped upside down to be bonded to the semiconductor structure ST1. For example, the bonding process may include adhering the bonding dielectric layer DL to the bonding dielectric layer DL′. FIG. 24 is a resulted structure after the bonding process. As a result, the channel layer 132 and the channel layer 132′ are vertically aligned with each other. In some embodiments, for achieving a CFET structure, the channel layer 132 and the gate structure 150 may serve as a p-type transistor, while the channel layer 132′ and the gate structure 150′ may serve as a n-type transistor stacked over the p-type transistor. For example, the gate structure 150 includes a p-type work function metal layer, and the channel layer 132 adjoins p-type source/drain regions (e.g., the source/drain regions SD in FIGS. 9 and 12), while the gate structure 150′ include a n-type work function metal layer, and the channel layer 132′ adjoins n-type source/drain regions (e.g., the source/drain regions SD in FIGS. 9 and 12). In some alternative embodiments, the channel layer 132 and the gate structure 150 may serve as a n-type transistor, while the channel layer 132′ and the gate structure 150′ may serve as a p-type transistor stacked over the n-type transistor. Other details of the present embodiments are similar to those illustrated in the embodiments in FIGS. 2A-9 and FIGS. 10-12, and thereto not repeated herein.

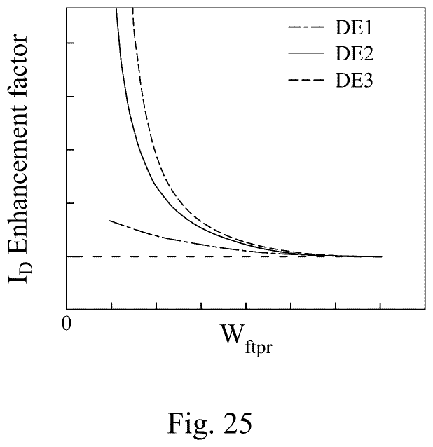

FIG. 25 is a diagram illustrating an enhancement factor of drive current versus a width of footprint of channel layers in semiconductor devices in accordance with some embodiments of the present disclosure. The horizontal axis represents the width the footprint of the channel layers (W_{ftpr}), which corresponds to the angle A1 in FIGS. 7C and 10 or the angle A2 in FIG. 18B. The vertical axis represents the enhancement factor of drive current (I_{D}). The line DE1-DE3 indicates the semiconductor devices with different aspect ratio, in which the aspect ratio is a ratio of the length 132H/224L of the nanofins 132/224 and the width 132W/224W of the nanofins 132/224 over a plane perpendicular to the current direction X (e.g., over the Y-Z plane). And, an aspect ratio of the semiconductor devices indicated by the line DE3 is greater than an aspect ratio of the semiconductor devices indicated by the line DE, and the aspect ratio of the semiconductor devices indicated by the line DE2 is greater than an aspect ratio of the semiconductor devices indicated by the line DE1. By controlling the angle A1/A2 (referring to FIGS. 7C, 10, and 18B) to increase, the width of footprint of the channel layers may decreases, the electrostatic control is improved to be more precise, and the stacking faults are reduced by minimizing the dislocation interface area. It is evidenced that the drive current (I_{D}) would increase as the width of footprint decreases. This diagram also shows that the enhancement of the drive current (I_{D}) is dominated by aspect ratio (AR) of the channel layers.

Based on the above discussions, it can be seen that the present disclosure offers advantages. It is understood, however, that other embodiments may offer additional advantages, and not all advantages are necessarily disclosed herein, and that no particular advantage is required for all embodiments. One of the advantages is that a non-horizontal nanosheet (also referred to as a nanofin) is designed to achieve ultra-scaling and enhance current density per footprint area. Another advantage is that the stackable nanofins can maintain scalability for fin pitch, contact poly pitch, and metal pitch down to the angstrom-generation. Still another advantage is that the nanofin architecture has significantly reduced stacking faults by minimizing the dislocation interface area. Still another advantage is that the nanofins can achieve a well electrostatic control and optimize electron mobility on NMOS. Still another advantage is that the stackable NanoFin is compatible with BSPDN down to the angstrom-generation.

According to some embodiments of the present disclosure, a method for manufacturing a semiconductor device includes patterning a semiconductor layer into a channel layer, wherein the semiconductor layer is over a dielectric layer on a substrate; removing a first portion of the dielectric layer below the channel layer to turn channel layer, such that a first end of the channel layer is higher than a second end of the channel layer; and forming a gate structure over the channel layer.

According to some embodiments of the present disclosure, a method for manufacturing a semiconductor device is provided. The method includes forming a stack over a dielectric layer, wherein the stack comprises a first channel layer, a second channel layer, and a sacrificial layer between the first and second channel layers, wherein the first and second channel layers are level with each other; etching the dielectric layer to turn the stack, such that the first channel layer is higher than the second channel layer; and replacing the sacrificial layer with a gate structure.

According to some embodiments of the present disclosure, a semiconductor device includes a substrate, at least one channel layer over the substrate, and a gate structure. The at least one channel layer is over the substrate. The at least one channel layer has a surface with (100) surface orientation, and the surface of the at least one channel layer is non-parallel to a top surface of the substrate. The gate structure surrounds the at least one channel layer and in contact with the surface of the at least one channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
patterning a semiconductor layer into a channel layer, wherein the semiconductor layer is over a dielectric layer on a substrate;
removing a first portion of the dielectric layer below the channel layer to turn channel layer, such that a first end of the channel layer is higher than a second end of the channel layer; and
forming a gate structure over the channel layer.

2. The method of claim 1, wherein the channel layer has a surface with (100) surface orientation, and removing the first portion of the dielectric layer is performed such that the surface of the channel layer is substantially normal to a top surface of the substrate.

3. The method of claim 1, wherein the channel layer has a surface with (100) surface orientation, and removing the first portion of the dielectric layer is performed such that the surface of the channel layer is tilted with respect to a top surface of the substrate.

4. The method of claim 1, wherein the channel layer has a surface with (100) surface orientation, and forming the gate structure is performed such that the gate structure is in contact with the surface of the channel layer.

5. The method of claim 1, wherein forming the gate structure is performed such that the gate structure wraps around the first and second ends of the channel layer.

6. The method of claim 5, further comprising:
forming source/drain regions on opposite sides of the gate structure.

7. The method of claim 1, wherein removing the first portion of the dielectric layer below the channel layer to turn the channel layer is performed such that a second portion of the dielectric layer remains, the first end of the channel layer is higher than a top end of the second portion of the dielectric layer, and the second end of the channel layer is below than the top end of the second portion of the dielectric layer.

8. The method of claim 7, further comprising:
removing the second portion of the dielectric layer prior to forming the gate structure.

9. A method for manufacturing a semiconductor device, comprising:
forming a stack over a dielectric layer, wherein the stack comprises a first channel layer, a second channel layer, and a sacrificial layer between the first and second channel layers, wherein the first and second channel layers are level with each other;
etching the dielectric layer to turn the stack, such that the first channel layer is higher than the second channel layer; and
replacing the sacrificial layer with a gate structure.

10. The method of claim 9, wherein forming the stack comprises:
etching an opening in a semiconductor layer to pattern the semiconductor layer into the first and second channel layers; and
forming the sacrificial layer in the opening.

11. The method of claim 9, wherein etching the dielectric layer to turn the stack comprise:
etching the dielectric layer into a dielectric protruding portion below the stack; and
causing the stack to fall down from the dielectric protruding portion.

12. The method of claim 11, further comprising:
removing the dielectric protruding portion prior to forming the gate structure.

13. The method of claim 9, wherein etching the dielectric layer is performed such that the first channel layer is directly above the second channel layer.

14. The method of claim 9, wherein forming the stack is performed such that the first and second channel layers are aligned with each other along a lateral direction, and a length of the first channel layer measured along the lateral direction is greater than a height of the first channel layer.

15. The method of claim 14, wherein forming the stack is performed such that the first and second channel layers are aligned with each other along a lateral direction, and a length of the first channel layer measured along the lateral direction is greater than a length of the sacrificial layer measured along the lateral direction.

16. A semiconductor device, comprising:
a substrate;
at least one channel layer over the substrate, wherein the at least one channel layer has a surface with (100) surface orientation, and the surface of the at least one channel layer is non-parallel to a top surface of the substrate; and
a gate structure surrounding the at least one channel layer and in contact with the surface of the at least one channel layer.

17. The semiconductor device of claim 16, wherein the surface of the at least one channel layer is substantially normal to the top surface of the substrate.

18. The semiconductor device of claim 16, wherein the surface of the at least one channel layer is tilted with respect to the top surface of the substrate.

19. The semiconductor device of claim 16, wherein a plurality of the channel layers are aligned with each other along a direction substantially normal to the top surface of the substrate.

20. The semiconductor device of claim 16, wherein a length of the at least one channel layer measured along a direction substantially normal to the top surface of the substrate is greater than a width of the at least one channel layer measured along a longitudinal direction of the gate structure.
